(19) United States
(12) Patent Application Publication
(10) Pub. No.: US 2003/0160711 A1
(43) Pub. Date: Aug. 28, 2003

(54) Potentiometer assembly providing an encoded output signal

(76) Inventors: Martin Bondo Jorgensen, Vaerlose (DK); Claus Erdmann Furst, Roskilde (DK)

Correspondence Address: HARNESS, DICKEY & PIERCE, P.L.C., P.O. BOX 8910, RESTON, VA, 20195, US

(21) Appl. No.: 10/239,147

(22) PCT Filed: Mar. 20, 2001
(86) PCT No.: PCT/DK01/00191

(30) Foreign Application Priority Data
Mar. 21, 2000 (DK) PA 2000-00470

(51) Int. Cl. H03M 1/22

(52) U.S. Cl. 341/16

(57) ABSTRACT

The present invention relates to a potentiometer assembly including a position sensing device and an integrated control circuit to form a potentiometer assembly providing an encoded output signal representing a position of a user operable control means. The encoded output signal may be in the form of a digital data signal or an encoded analogue signal representing the position of the user operable control means so that an external device, such as a Digital Signal Processor (DSP) or microprocessor, may read and decode the encoded output signal. In particular, the present invention is suitable for use in compact electronic equipment, such as mobile phones and hearing instruments. Such equipment will benefit from the versatile functionality of the potentiometer assembly according to the present invention allowing a broad range of applications to be supported.

### FIELD OF THE INVENTION

The present invention relates to a potentiometer assembly that integrates a position sensing device and an integrated control circuit to form a potentiometer assembly providing an encoded output signal representing a position of a user operable control means. The encoded output signal may comprise a digital data signal or an encoded analogue signal that represents the position of the user operable control means so that an external device, such as a Digital Signal Processor (DSP) or microprocessor, may be adapted to read and decode the encoded output signal. The external device will typically form part of a piece of electronic equipment adapted to respond to the encoded output signal. The present invention is particularly well adapted for use in compact electronic equipment, such as mobile phones and hearing instruments, that will benefit from the versatile functionality of the present potentiometer assembly allowing a broad range of applications to be supported.

### BACKGROUND OF THE INVENTION

Electronic equipment such as hearing instruments, mobile phones, medical dispensing devices etc. typically require that one or several functions provided by the equipment are user controllable. Even though a lot of effort is spent on developing automatic and “intelligent” control programs and functions for users of such electronic equipment, many users still want to be able to, at least ultimately, intervene in the automatic function.

In the field of hearing instruments or aids, effort has been spent on developing control algorithms that are capable of automatically adapting a gain or a frequency response of the instrument to various listening environments in which the hearing aid user must be able to communicate. This is particularly the case for the current generation of DSP-based hearing instruments wherein the utilisation of powerful processors supports the development of such control algorithms. Nevertheless, it has been found that many users request hearing aids that include an option for manual intervention in e.g. frequency response settings or gain settings selected by such automatic control algorithms. Furthermore, traditional potentiometers and trimmers, which typically operate by providing a variable resistance in an audio signal path or a variable voltage division of audio signals within the hearing aid, are not well adapted for applications with DSP based controllers. Usually, such DSP based controllers are designed to communicate, and respond to, digitally encoded signals or data signals.

Consequently, there is a need for potentiometer assemblies that provide an encoded output signal, preferably a digitally encoded output signal, representing the position of the user operable control means. Furthermore, miniature versions of such potentiometer assemblies are particularly advantageous for use in a growing number of applications in the fields of body-worn and hand-held compact electronic devices.

### SUMMARY OF THE INVENTION

It is an object of the invention to provide a potentiometer assembly suitable for integration within compact electronic equipment, such as hearing instruments, mobile phones, portable audio equipment etc.

It is also an object of the invention to provide a potentiometer assembly which may provide a digital data signal representing the position of a user operable control knob so as to support seamless integration with microprocessors including Digital Signal Processors.

A first aspect of the invention relates to a potentiometer assembly providing an encoded output signal, the assembly comprising:

a base and a user operable control means,

a number of externally accessible terminals,

a substrate carrier comprising a position sensing device adapted to detect a position of the user operable control means and to provide a position signal indicating the position of the user operable control means,

an integrated control circuit adapted to receive the position signal to generate an encoded output signal representing a value of the position signal wherein the integrated control circuit is further adapted to provide the encoded output signal on a first terminal of the number of externally accessible terminals.

The term “user operable control means” designate control means such as a control knob or button that is operable by a human operator. This human operator may be an individual carrying a piece of electronic equipment housing the present potentiometer assembly, i.e. a user, or it may be specially trained operator, such as a technician, a medical doctor or a hearing aid dispenser that operates the control means e.g. in connection with customising the piece of electronic equipment to particular requirements/wishes of the user. The user operable control means may be adapted to respond to an applied pressure force or torque.

The position sensing device may operate according to a number of differing principles. A capacitive position sensing may be utilised wherein the position signal is provided by changing a value of a sense capacitance in response to a change in the position of the user operable control means. The sensing capacitance may form part of signal path of an oscillator to control an oscillation frequency of the position signal. Accordingly, by detecting the oscillation frequency such a position signal, the position of the user operable control means may be determined. Alternatively, a magnetic field sensitive device may be utilised to detect the position the user operable control means by sensing a direction of a magnetic field. A suitable switched MAGFET device that is capable of resolving the direction of an applied magnetic field is described in the applicant's U.S. Pat. No. 5,920,090.

The integrated control circuit may be constituted by proprietary Application Specific Integrated Circuit (ASIC) having characteristics specifically tailored to the characteristics of the associated position sensing device. This integrated control circuit is preferably designed in CMOS technology wherein a large number of logic functions or gates can be integrated on a very small die area. Furthermore, CMOS technology also allows the integrated control circuit to be manufactured at very low costs due to the wide-spread use of CMOS in today's digital circuits. Alternatively, BiCMOS or Bipolar technologies may be utilised to provide higher performance analogue circuitry, if required, such as proprietary low-power and/or high precision analogue-to-digital converters.

According to a preferred embodiment of the invention the position sensing device comprises a semi-circular resistance element being connected between a first reference voltage and a second reference voltage, and a moveable wiper contacting a part of the resistance element to provide the position signal as a wiper voltage. This embodiment facilitate reuse of a number of already existing potentiometer parts that are compatible with existing manufacturing processes and equipment. Accordingly, it is possible to produce potentiometer assemblies in a rapid and cost-effective manner by utilising this embodiment of the invention. The first and second reference voltages may be DC-voltages such as a battery voltage or other supply voltage and Ground, respectively.

The integrated control circuit may be adapted to provide the encoded output signal as a Pulse Width Modulated (PWM) signal. The value of the position signal may be coded into the PWM signal by generating PWM pulses with widths proportional to values of the position signal. An external device, such as a microprocessor or Digital Signal Processor (DSP), may have a digital input port which may be utilised read the PWM signal by performing consecutive readings of a logic level of the PWM signal. If the readings of the digital input port are performed at a rate much higher than the widths of the PWM pulses, the PWM signal can readily be decoded.

Alternatively, the encoded output signal may comprise a digital data signal in a format that is compatible with data formats of target microprocessors or DSPs. These processors often contain one or several programming ports suitable for e.g. serial data communication with external devices.

To provide a compact potentiometer assembly occupying a minimum of space within the piece of electronic equipment, the integrated control circuit may be mounted on an upper or a lower surface of the substrate carrier. By this arrangement, an already existing area of the substrate carrier may be utilised to hold the integrated control circuit so as to provide a very compact assembly having identical outer dimensions to already existing potentiometer or trimmer types. Accordingly, by utilising this embodiment of the present potentiometer assembly it is possible to provide a mechanical drop-in replacement potentiometer assembly that fits existing electronic equipment casings or housings.

According to a preferred embodiment of the invention, the position sensing device is provided in the form of the semi-circular resistance element and the moveable wiper arranged on the upper surface of the substrate carrier. The integrated control circuit is mounted on the lower surface of the substrate carrier. Plated through-holes are preferably provided to form one or several electrical connections between the upper surface and the lower surface of the substrate carrier to convey the first and second reference voltages to respective end parts of the semi-circular resistance element and to convey the wiper voltage to the integrated control circuit. Preferably, the resistance element is a substantially linear resistance element providing a substantially fixed resistance per unit length or per unit angle of the resistance element. Such a linear resistance element is relatively simple to manufacture in comparison with often used logarithmic resistance elements that often are required to control gain or frequency responses in analogue audio-equipment, such as hearing instruments based on analogue signal processing.

If a logarithmic representation of the position signal is required, this may be accomplished by adapting the integrated control circuit to perform a logarithmic conversion of the linear position signal, that is preferred to generate in the present potentiometer assembly, and subsequently basing the encoded output signal on such a logarithmically converted position signal.

The number of externally accessible terminals may be formed on respective conductors of an end part of an elongate flexible substrate or circuit strip. In this embodiment of the invention, another end part of the flexible substrate or circuit strip having the respective conductors arranged thereon may be connected to respective substrate carrier conductors. This connection may be provided by means of welding processes, gluing, bonding etc. Accordingly, the potentiometer assembly according to this embodiment may be integrated with the flexible circuit strip that provides the number of externally accessible terminals so as to form a single unit comprising both the assembly and associated electrical leads required for supply of power and for communication with e.g. a microprocessor. Such a single unit is simple to handle and well-suited for automated manufacturing processes.

Alternatively, the number of externally accessible terminals may be provided as respective conductive pins protruding through the base and being attached to the substrate carrier. In this embodiment of the potentiometer assembly, one or several pins of the respective conductive pins may be electrically connected to respective conductors arranged on the lower surface to the substrate carrier so as to provide electrical connection(s) to respective terminal(s) of the integrated control circuit. Preferably, at least a power supply and ground connection is provided on the respective conductive pins to form respective power and ground terminal(s) for the integrated control circuit.

The substrate carrier is preferably formed in a printed circuit board or is at least comprising a printed circuit board. Alternatively, the substrate carrier may comprise a ceramic hybrid substrate or it may be formed in a silicon substrate. By forming the substrate carrier in a silicon substrate it may be possible to further integrate the position sensing device and/or the integrated circuit or at least a part of these components in the substrate.

To isolate the integrated control circuit from the environment external to the potentiometer assembly, the assembly may be designed so that the base and the substrate carrier are adapted to abut each other. A part of the base facing the lower surface of the substrate carrier may further comprise a depression so as to form a shielding cavity enclosing the integrated control circuit between the part of the base and the substrate carrier when the base and the substrate carrier abut. This embodiment of the present potentiometer assembly possesses several advantages. The shielding cavity functions as a barrier against contamination such as moisture, sweat, dust etc. in the external environment. Furthermore, most integrated circuits are light sensitive to some degree so it is usually required to shield light away from an integrated circuits. This light shielding has also been secured by enclosing the integrated control circuit in the shielding cavity. Additional environmental shielding may further be added to the potentiometer assembly by filling up the shielding cavity, or at least the depression in the base, with an epoxy coating before the cavity is closed.

According to another preferred embodiment of the invention, the integrated control circuit comprises an analogue-to-digital converter having a first and a second power supply terminal and being adapted sample the position signal to provide a digital value representing the value of the position signal. Furthermore, the encoded output signal is based on the digital value. The digital value may be a substantially linear representation of the value of the position signal provided by e.g. a sigma-delta analogue-to-digital converter or a successive approximation converter. Alternatively, the analogue-to-digital converter may be adapted to convert the value of the position signal into an intermediate digital value of linear representation while an encoder circuit of the converter subsequently converts this linear digital value to a logarithmic digital value. The encoder circuit may comprise a ROM or EPROM pre-stored conversion table so that logarithmic values corresponding to linear digital values may be found by table look-up. These logarithmic digital values may be also be provided by a direct calculation in suitable processing means within the integrated control circuit or the analogue-to-digital converter itself.

Alternatively, the analogue-to-digital converter may be adapted to directly convert the value of the position signal into a digital value which is a substantially logarithmic representation of the position signal, and hence of the position of the user operable control means.

If the analogue-to-digital converter is utilised to sample and convert the position signal, it is preferred that 5-10 bits resolution of the position signal is used leading to a digital value of 5-10 bits. The encoded output signal could be an analogue signal in this situation but is preferably provided as a digital data signal comprising the same number of data bits as in the digital value. The 5-10 bits resolution of the position signal provides the potentiometer assembly with a dynamic range from about 30 dB to about 60 dB which is sufficient for many audio-related applications that involves gain control or frequency response control. For hearing aid applications in particular, it is preferred to utilise about 5-6 bits resolution of the position signal in order to conserve power and die area usage of the converter. Thereby, a volume control may have 32 or 64 discrete steps. If the position sensing device is implemented by utilising the resistance element connected between the first and second reference voltages, the first reference voltage may also be applied to the first power supply terminal of the analogue-to-digital converter and the second reference voltage applied to the second power supply terminal of the analogue-to-digital converter. Accordingly, variations in the wiper voltage caused by variations in one of the reference voltages are tracked by the analogue-to-digital converter and thus do not introduce measurement errors of the wiper voltage representing the position of the user operable control means.

The operation of the analogue-to-digital converter including sampling of the value of the position signal may be controlled by logic circuitry, e.g. in the form of a simple hardwired internal processor, within the integrated control circuit. The value of the position signal may be determined at regular time intervals and the digital value updated at regular time intervals under the control of such an internal processor or other logic means. Preferably, the regular time interval is a time interval less than about 1000 ms, or more preferably less than 500, or less than 200 ms, or even more preferably less than 100 ms such as less than 50 ms. It has been found that a time interval between 50 ms and 200 ms is suitable for users in many applications of the present potentiometer assembly. Regular time intervals of this magnitude are sufficiently short to eliminate annoying “delay effects” that can make it difficult for the user to obtain a desired setting of the user operable control means.

Alternatively, the integrated control circuit may be adapted to update the digital value solely in response to a detected change in the position signal, and thereby of the user operable control means, to provide an encoded output signal representing a new position of the user operable control means. This embodiment of the invention is particular advantageous for low-power applications and/or applications wherein the user operable control means are seldom manipulated, since it is possible to interrupt transmission of the encoded output signal between detected changes in the position signal to conserve power. If an analogue-to-digital converter is utilised to sample the position signal and generate the digital value, this converter may be adapted to enter a power conserving mode between detected changes of the position signal.

The integrated control circuit may be adapted to transmit the encoded output signal one or several times in response to the detected change in the position signal and subsequently interrupt the encoded output signal until a next change of position of the user operated control means is detected. The interruption of the encoded output signal is preferably implemented by utilising an integrated data transmission buffer with a high impedance state to transmit the encoded output signal. By activating the high impedance state of the data transmission buffer, the transmission of the digital data signal may be interrupted. Several types of data transmission buffers may be utilised, such CMOS or Bipolar tri-state buffers or open collector/drain output buffers etc.

Alternatively, the integrated control circuit may be adapted to continuously transmit the encoded output signal (when a power supply is present). This operation mode may be advantageous in applications where it is desirable, or required, that the current position of the user operable control means always can be determined, i.e. independent of whether or not the user operable control means recently have manipulated. This could be relevant if the current position of the user operable control means is required for operating a piece of electronic equipment intermediately after it has performed a power up sequence and thus may be unaware of the correct current position.

In yet another embodiment of the invention, the integrated control circuit is adapted to sample the value of the position signal and update the digital value in response to a trigger signal supplied by an external device to a second terminal of the number of externally accessible terminals. This trigger signal may comprise a single pulse of a predetermined voltage level and/or of a predetermined duration or the trigger signal may comprise a sequence of pulses constituting a series of bits encoding a particular data pattern to which the integrated control circuit is adapted to respond. Alternatively, the integrated control circuit may be adapted to solely perform a sampling of the value of the position signal and a subsequent update the digital value in response to a presence of an external clock signal and otherwise enter the power saving mode. A clock detecting unit senses whether the external clock signal is present or not, and optionally whether the external clock signal is valid based on certain predetermined characteristics. Accordingly, may this operation mode be viewed as a “trigger sensitive” mode, wherein the trigger signal is constituted by the external clock signal. Thereby, the external device may control the operation of the integrated control circuit and put it into the power saving mode by removing the external clock signal.

The integrated control circuit may, however, comprise its own clock generator providing one or several clock signals to control operations of the integrated control circuit. Such clock signals from an integrated clock generator may be utilised to clock a processor and/or the analogue-to-digital converter and/or correctly control a timing of the encoded output signal. By utilising one of the internally generated clock signals to control the timing of the encoded output signal, synchronous communication with the external device is supported. However, it is presently preferred to dispense with such a clock generator on the integrated control circuit in order to conserve power and die area. Instead clocking of the internal processor and/or the analogue-to-digital converter is preferably accomplished by adapting the integrated control circuit to receive an external clock signal from the external device to perform the clocking of the integrated control circuit. The second terminal or a third terminal of the number of externally accessible terminals may be used for external clock reception. This clocking scheme also supports synchronous communication with the external device, since the external clock signal may control the timing of the encoded output signal from the integrated control circuit to the external device.

Furthermore, to save a terminal on the potentiometer assembly, the external clock signal and a power terminal may be integrated so that the voltage supply is conveyed to the integrated control circuit over the external clock line. This integrated functionality could be accomplished by using the external clock signal to drive an AC to DC voltage converter on the integrated control circuit.

In some embodiments of the present invention, the integrated control circuit may be adapted to provide bi-directional communication of digital data signals over the first terminal to/from the external device so as to receive external device data. Such external device data may be utilised by the integrated control circuit to customise various functions, such as controlling a transmission format of the digital data signal or selecting between providing the encoded output signal as a digital data signal or an analogue PWM signal. The external device data may also select whether the digital data signal is outputted as a linear representation or a logarithmic representation of the position signal.

The bi-directional communication of digital data signals between the external device and the integrated control circuit may be performed according to the IIC or IIS serial communication protocols. These serial communication protocols are already supported by a huge amount of commercially available microprocessor and DSPs and several proprietary DSPs.

### BRIEF DESCRIPTION OF THE DRAWINGS

Hereunder, a preferred embodiment of a potentiometer assembly according to the invention is described with reference to the drawings, wherein

FIG. 1 is an exploded view of the potentiometer assembly showing an upper surface of a substrate carrier with a resistor element,

FIG. 2 is an exploded view of the potentiometer assembly showing a lower surface of the substrate carrier with an integrated control circuit attached thereto,

FIG. 3 is an illustration of the potentiometer assembly shown in FIGS. 1 and 2 in an assembled state,

FIG. 4 is a more detailed exploded view of the potentiometer assembly shown in FIGS. 1,2 and 3, and

FIG. 5 is an illustration of a proposed output format of a digital data signal of the potentiometer assembly representing the position of a user operable control knob.

### DETAILED DESCRIPTION OF A PREFERRED EMBODIMENT

The present embodiment of the potentiometer assembly is designed to be capable of operating as a “digital” volume control in hearing instrument applications. Accordingly, the integrated control circuit must be designed to operate on voltage supplies from about 1.50 Volts to about 0.9 Volts with an average current consumption of about 50 PA or less.

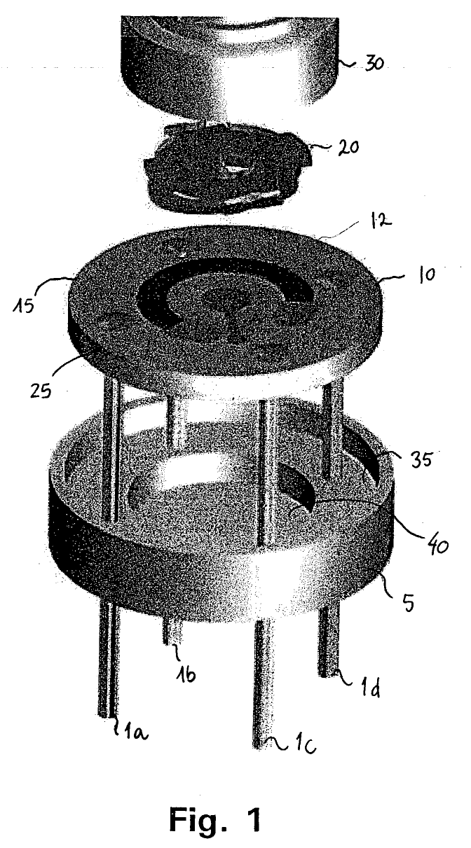

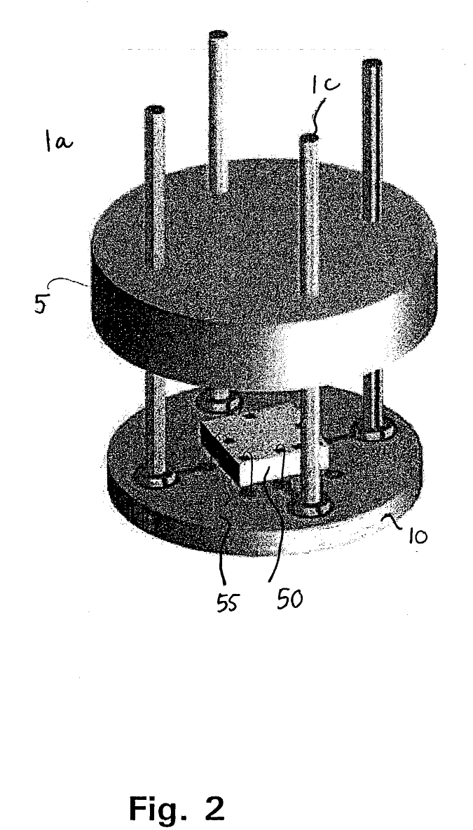

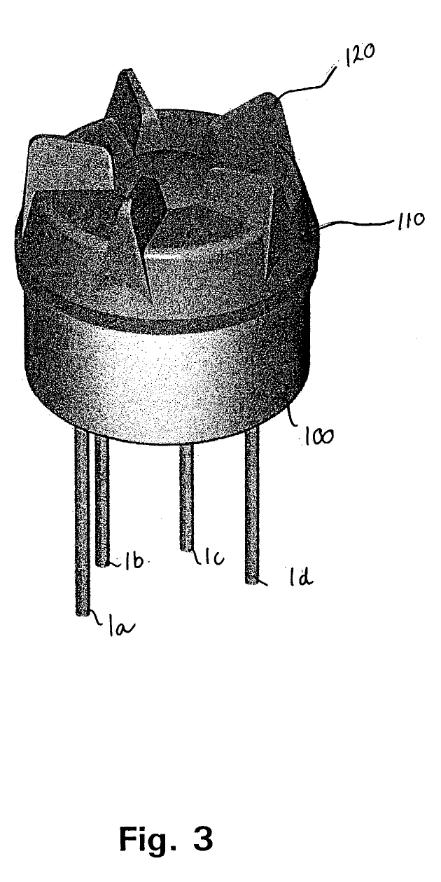

In FIG. 1, four electrical conductive pins 1a-1d protrude through a circular potentiometer base of plastic 5. The four electrical conductive pins 1a-1d are riveted to a substrate carrier 10 in the form of a double sided printed circuit board. A semi-circular resistor element 15 is arranged on an upper surface 12 of the double sided printed circuit board 10. A rotatable member 20 provides an electrical contact point on the resistor element 15 so as to form a variable potentiometer wiper. The rotatable member 20 is in turn attached to a contact member 30 which is responsible for biasing the rotatable member 20 with a force that secures stable electrical connection between the member 20 and the semi-circular resistor element 15. The contact member 30 is furthermore connected to a user operable control knob (item 110, FIG. 3) so that rotation of this control knob is conveyed to the rotatable member 20. A plated through hole 25 located in between end parts of the semicircular resistor element 15 provides electrical connection from the wiper voltage to a conductor located on a lower surface 55 of the printed circuit board 10 (illustrated in FIG. 2).

FIG. 2 shows an integrated control circuit 50 attached to the lower surface 55 of the printed circuit board 10. Wire bonding has been utilised to provide electrical connections between pads on the integrated control circuit 50 and a number of corresponding electrical conductors disposed on the lower surface 55. The electrical conductive pins 1a and 1d are battery supply and ground connections, respectively. Corresponding electrical conductor on the lower surface provide supply voltages to the bonding pads disposed on the lower surface 55 so that the integrated control circuit 50 can be connected to an appropriate voltage supply.

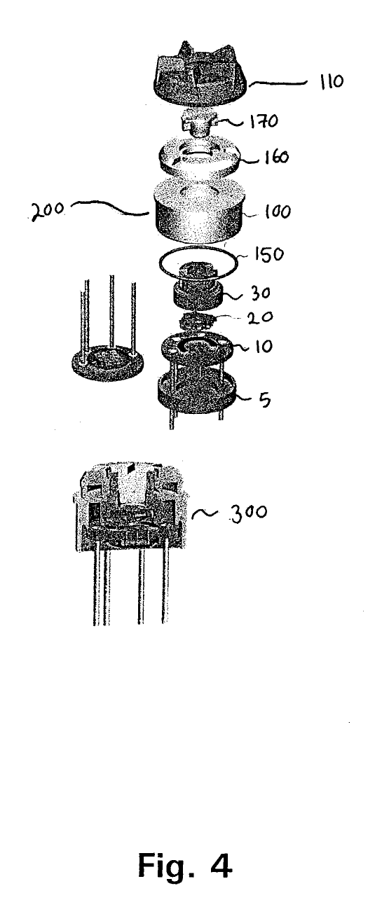

A shown on FIG. 1, a part of the circular base 5 facing the lower surface of the double sided printed circuit board 10 is provided with two circular depressions, an outer depression 35 and an inner depression 40. A circular edge part of the printed circuit board 10 fits into the circular outer depression 35 in the base 5 so that when the base 5 and the printed circuit board 10 are joined, a substantially liquid and dust proof sealing is provided between the external environment and a cavity formed by the circuit board 10 and the inner circular depression 40. FIG. 3 illustrates an assembled state of the present potentiometer assembly. A rotatable user operable control knob 110 is mounted on the potentiometer base 5 and provided with a number of protrusions 120 on a front surface to assist the user in manipulating the control knob 110. The present potentiometer assembly has been designed so that the rotational angle of the user operable control knob 110 is about 270 degrees, since this rotation angle causes the wiper to transverse the semi-circular resistance element 15 from a first to a second end point. Electrical connections to the interior of a hearing instrument are provided by electrical leads soldered to the gold plated electrical pins 1a-1d. A circular jacket 100 covers the potentiometer base 5 and other interior components (see description of FIG. 4 below) of the potentiometer assembly. The circular jacket 100 is mounted in an aperture of a corresponding diameter moulded in the hearing instrument casing or housing, typically in a face plate of an ITE or ITC hearing aid. Accordingly, the control knob 110 protrudes from a surface part of the ITE or ITC hearing aid and can be manipulated by the hearing aid user to control the gain of the aid.

FIG. 4 comprises a detailed exploded view 200 of the potentiometer assembly shown in FIGS. 2 & 3 disclosing a number of additional miniature mechanical components and a vertical sectional view 300 of the potentiometer assembly.

The detailed exploded view 200 shows additional miniature mechanical components comprising a sealing ring 150 that functions to provide a contamination barrier between the above-mentioned jacket 100 surrounding the potentiometer base 5 and the upper surface of the double sided printed circuit board 10. An adapter element 170 conveys any torque applied to the control knob 110, in order to select a new position of the potentiometer assembly, to the contact member 30. The contact member 30 in turn, by its substantially rigid connection to the rotatable member 20, changes the position of the wiper on the resistance element 15 to reflect the new position of the control knob. The adapter 160 fixes the maximum rotational angle of the control knob 110 due to its provision of mechanical end stops.

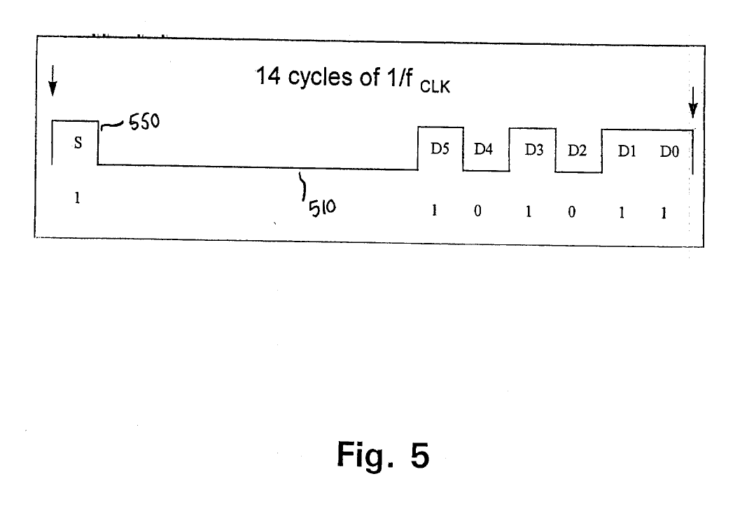

FIG. 5 illustrates a preferred output format for a digital data signal 510 provided by the present potentiometer assembly. The digital data signal has been obtained by utilising an analogue-to-digital converter sampling a value of the wiper voltage and converting the sampled wiper voltage into a corresponding 6 bit digital value. This digital value is preferably stored in an internal register of the integrated control circuit. The operation of the integrated control circuit 50 is controlled by an external clock signal provided over external terminal 1d. The use of the external clock signal has the advantage that a power and die area consuming internal clock generator is superfluous. A frequency of the external clock signal is preferably selected within the interval 2-100 kHz, such as about 32 kHz. The integrated control circuit operates by solely updating the digital value and transmitting the digital data signal one time in response to a detected change in the position signal, and thereby of the user operable control means. As illustrated in FIG. 5, the format of the digital data signal has been defined so that the default logic state of the digital data signal is low or “0”. When an update of the digital value has been performed in response to a detected change in the position of the control knob 110, the transmission of the digital data signal begins by a start bit 500 immediately followed by seven “0” bits so as to form an recognisable data pattern to mark the beginning of a new digital value to the external device.

Immediately thereafter the six bits of data (D5-D0) representing the current digital value, and thereby the new position of the user operable control knob 110, are transmitted one time. Since the transmission of the digital data signal begins by the transmission of the start bit 500, a rising or a falling edge of this start bit may conveniently be utilised to generate an interrupt to an external DSP or microprocessor having a suitable edge sensitive input port. An interrupt routine may afterwards read and decode the received digital data signal.

1. A potentiometer assembly providing an encoded output signal, the assembly comprising:
a base and a user operable control means,
a number of externally accessible terminals,
a substrate carrier comprising a position sensing device adapted to detect a position of the user operable control means and to provide a position signal indicating the position of the user operable control means,
an integrated control circuit adapted to receive the position signal to generate an encoded output signal representing a value of the position signal,
the integrated control circuit being further adapted to provide the encoded output signal on a first terminal of the number of externally accessible terminals.

2. A potentiometer assembly according to claim 1, wherein the position sensing device comprises a resistance element being connected between a first reference voltage and a second reference voltage, and a moveable wiper contacting a part of the resistance element to provide the position signal as a wiper voltage.

3. A potentiometer assembly according to claim 1 or 2, wherein the encoded output signal comprises a Pulse Width Modulated signal.

4. A potentiometer assembly according to claim 1 or 2, wherein the encoded output signal comprises a digital data signal.

5. A potentiometer assembly according to any of the preceding claims, wherein the integrated control circuit is mounted on an upper or a lower surface of the substrate carrier.

6. A potentiometer assembly according to any of claims 2-5, wherein the resistance element is arranged on the upper surface of the substrate carrier and the integrated control circuit is mounted on the lower surface of the substrate carrier.

7. A potentiometer assembly according to any of the preceding claims, wherein the number of externally accessible terminals is formed on respective conductors of an end part of an elongate flexible substrate or circuit strip.

8. A potentiometer assembly according to any of the preceding claims, wherein the number of externally accessible terminals is provided as respective conductive pins protruding through the base and being attached to the substrate carrier.

9. A potentiometer assembly according to claim 8, wherein one or several pins of the respective conductive pins is/are electrically connected to respective conductors arranged on the lower surface to the substrate carrier so as to provide electrical connection(s) to respective terminal(s) of the integrated control circuit.

10. A potentiometer assembly according to any of the preceding claims, wherein the substrate carrier comprises a printed circuit board.

11. A potentiometer assembly according to any of the preceding claims, wherein the base and the substrate carrier are adapted to abut each other, and a part of the base facing the lower surface of the substrate carrier comprises a depression so as to form a shielding cavity enclosing the integrated control circuit between the part of the base and the substrate carrier.

12. A potentiometer assembly according to any of the preceding claims, wherein the resistance element is a substantially linear resistance element providing a substantially fixed resistance per unit length or per unit angle of the resistance element.

13. A potentiometer assembly according to any of the preceding claims, wherein the integrated control circuit comprises an analogue-to-digital converter having a first and a second power supply terminal and being adapted sample the position signal to provide a digital value representing the value of the position signal,
the encoded output signal being based on the digital value.

14. A potentiometer assembly according to claim 13, wherein the digital value is a substantially linear representation of the value of the position signal.

15. A potentiometer assembly according to claim 13, wherein the digital value is a substantially logarithmic representation of the value of the position signal.

16. A potentiometer assembly according to any of claims 13-15, wherein the digital value is represented in the form of a 5-10 bits binary value.

17. A potentiometer assembly according to any of claims 13-16, wherein the integrated control circuit is adapted to determine the value of the position signal and update the digital value at regular time intervals.

18. A potentiometer assembly according to claim 17, wherein the regular time interval is a time interval less than 100 ms or less than 200 ms or less than 500 ms or less than 1000 ms.

19. A potentiometer assembly according to any of claims 13-16, wherein the integrated control circuit is adapted to update the digital value in response to a detected change in the position signal to provide an encoded output signal representing a new position of the user operable control means.

20. A potentiometer assembly according to claim 19, wherein the integrated control circuit is adapted to transmit the encoded output signal one or several times in response to the detected change in the position signal, and
adapted to subsequently interrupt the encoded output signal until a next change of position of the control means is detected.

21. A potentiometer assembly according to claim 20, wherein the integrated control circuit comprises a data transmission buffer with a high impedance state and being adapted to transmit the encoded output signal the one or several times, and
the interruption of the encoded output signal being performed by activating the high impedance state of the data transmission buffer.

22. A potentiometer assembly according to any of claims 13-16, wherein the integrated control circuit is adapted to sample the value of the position signal and update the digital value in response to a trigger signal supplied by an external device to a second terminal of the number of externally accessible terminals.

23. A potentiometer assembly according to any of the preceding claims, wherein the integrated control circuit comprises a clock generator providing one or several clock signals to control operations of the integrated control circuit.

24. A potentiometer assembly according to any of the preceding claims, wherein the integrated control circuit is adapted to receive an external clock signal from an external device over a third terminal of the number of externally accessible terminals,
the external clock signal controlling the transmission of the encoded output signal from the integrated control circuit.

25. A potentiometer assembly according to claim 24, wherein the integrated control circuit is adapted to communicate bi-directional digital data signals over the first terminal to/from the external device so as to receive external device data.

26. A potentiometer assembly according to claim 22, wherein the integrated control circuit is adapted to store and decode the external device data and adapted to control a transmission format of the digital data signal provided by the control circuit in accordance with the external device data.

27. A potentiometer assembly according to any of claims 25-26, wherein the external clock signal and the digital data signals communicated between the external device and the integrated control circuit are communicated according to the IIC protocol.

28. A potentiometer assembly according to any of claims 13-27, wherein the first reference voltage is provided to the first power supply terminal of the analogue-to-digital converter and the second reference voltage is provided to the second power supply terminal of the analogue-to-digital converter.
